(19) United States
(12) Patent Application Publication
(10) Pub. No.: US 2026/0324092 A1
(43) Pub. Date: Oct. 15, 2026

(54) TRANSIENT VOLTAGE SUPPRESSION DIODE

(71) Applicant: Vanguard International Semiconductor Corporation, Hsinchu (TW)

(72) Inventors: Hui-Zhi Chen, Hsinchu County (TW); Yu-Hao Ho, Hsinchu City (TW); Po-Chung Chen, Hsinchu City (TW)

(73) Assignee: Vanguard International Semiconductor Corporation, Hsinchu (TW)

(21) Appl. No.: 19/176,109

(22) Filed: Apr. 10, 2025

(51) Int. Cl. H10D 89/60

(52) U.S. Cl. CPC H10D 89/611

(57) ABSTRACT

A transient voltage suppression diode includes a substrate having a first conductivity type. A first well region has a second conductivity type and is disposed in the substrate. A first contact region has the first conductivity type, is disposed in the first well region and electrically coupled to an input terminal. A second well region has the first conductivity type, is disposed in the substrate and laterally separated from the first well region. A second contact region has the second conductivity type, is disposed in the second well region and electrically coupled to a ground terminal. In addition, an isolation region is disposed in the substrate and surrounds side surfaces of the first well region.

### BACKGROUND OF THE INVENTION

### 1. FIELD OF THE INVENTION

The present disclosure relates generally to semiconductor devices, and more particularly to transient voltage suppression diodes.

### 2. DESCRIPTION OF THE PRIOR ART

A transient voltage suppression diode (TVS diode) is a component used for overvoltage and electrostatic discharge (ESD) protection. A TVS diode is usually connected in parallel with the circuit to be protected. When the circuit is operating normally, the TVS diode is off, consuming only a small leakage current and not affecting normal circuit operation. When an overvoltage, such as a surge, is applied to the circuit and reaches the breakdown voltage of the TVS diode, the TVS diode turns on and conducts a pulse current to suppress the excessive voltage above its breakdown voltage, thereby clamping the overvoltage and protecting the downstream circuit. However, current TVS diodes still cannot fully meet various requirements, such as those posed by the trend toward high-speed transmission.

### SUMMARY OF THE INVENTION

In view of this, the present disclosure provides transient voltage suppression (TVS) diodes that block a lateral PN junction between a substrate and a well region of opposite conductivity types. An isolation region is disposed on the sides of the well region and blocks the lateral PN junction, thereby reducing the PN junction area and making the depletion region smaller. Therefore, the capacitance of the TVS diode is reduced, and the response time of the TVS diode is shortened to meet the requirements of high-speed transmission.

According to an embodiment of the present disclosure, a transient voltage suppression diode is provided and includes a substrate, a first well region, a first contact region, a second well region, a second contact region, and an isolation region. The substrate has a first conductivity type. The first well region has a second conductivity type and is disposed in the substrate. The first contact region having the first conductivity type is disposed in the first well region and electrically coupled to an input terminal. The second well region having the first conductivity type is disposed in the substrate and laterally separated from the first well region. The second contact region having the second conductivity type is disposed in the second well region and electrically coupled to a ground terminal. The isolation region is disposed in the substrate and surrounds side surfaces of the first well region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic top view of a transient voltage suppression (TVS) diode according to an embodiment of the present disclosure.

FIG. 2 is a schematic top view of a TVS diode according to another embodiment of the present disclosure.

FIG. 3 is a schematic cross-sectional view of a TVS diode according to some embodiments of the present disclosure, which is taken along the line A-A’ in FIG. 1 and the line A-A’ in FIG. 2.

FIG. 4 is a schematic cross-sectional view of a TVS diode according to an embodiment of the present disclosure, which is taken along the line B-B’ in FIG. 2.

FIG. 5 is a schematic top view of a TVS diode according to another embodiment of the present disclosure.

FIG. 6 is a schematic cross-sectional view of a TVS diode according to another embodiment of the present disclosure, which is taken along the line C-C’ in FIG. 5.

FIG. 7 is a schematic cross-sectional view of a TVS diode according to another embodiment of the present disclosure, which is taken along the line D-D’ in FIG. 5.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as "below" and/or "beneath" other elements or features would then be oriented "above" and/or "over" the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as "first," "second," and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms "coupled to" and "electrically connected to" include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to transient voltage suppression (TVS) diodes including an isolation region formed on the sides of a first well region by etching a substrate and filling it with a dielectric or insulating material. The first well region has a conductivity type opposite to that of the substrate. The isolation region surrounds the periphery of the first well region to block the PN junction between the substrate and the sides of the first well region, thereby reducing the PN junction area and making the depletion region smaller. Therefore, the capacitance of the TVS diodes is reduced, and the response time of the TVS diodes is shortened to meet the requirements of high-speed transmission.

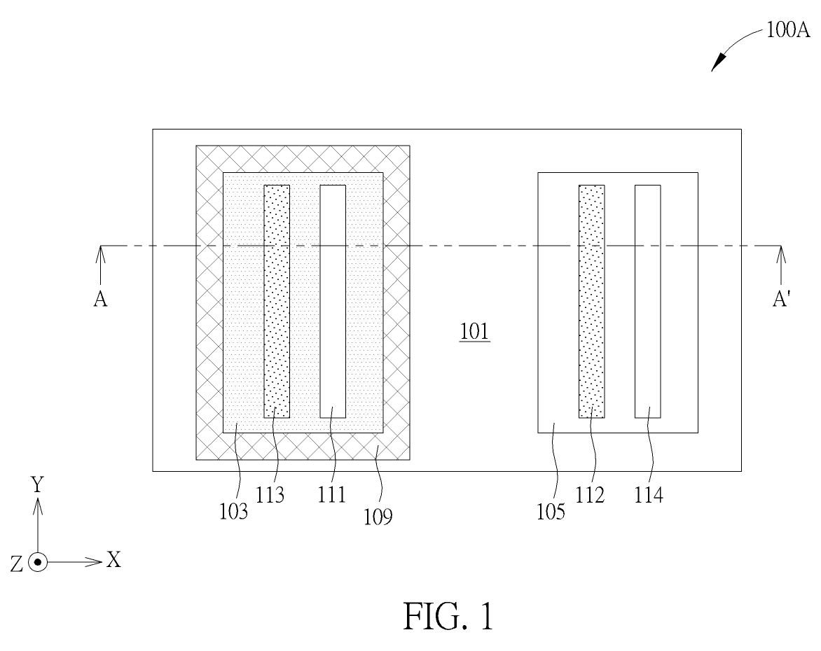

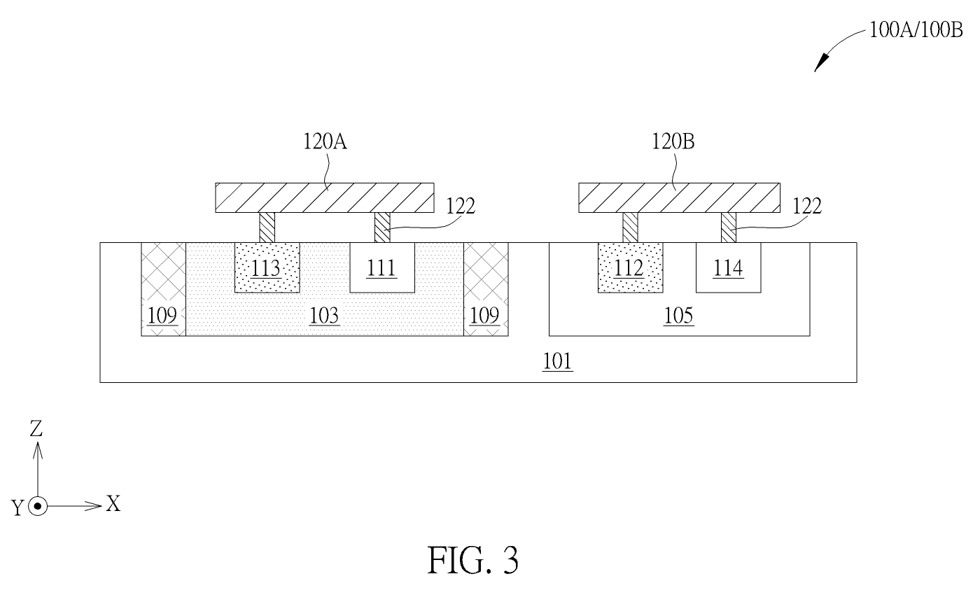

FIG. 1 is a top view of a TVS diode 100A according to an embodiment of the present disclosure. FIG. 3 is a cross-sectional view of the TVS diode 100A taken along the line A-A’ in FIG. 1 according to an embodiment of the present disclosure. As shown in FIGS. 1 and 3, the TVS diode 100A includes a substrate 101 having a first conductivity type, such as a p-type substrate. The substrate 101 may be made of silicon (Si), germanium (Ge), silicon carbide (SiC), silicon germanium (SiGe), or a group III-V compound semiconductor, such as gallium nitride (GaN), gallium arsenide (GaAs), aluminum nitride (AlN), aluminum gallium nitride (AlGaN), indium aluminum gallium nitride (InAlGaN), indium gallium nitride (InGaN), aluminum gallium arsenide (AlGaAs), indium gallium arsenide (InGaAs), other similar compound semiconductors, or a combination thereof. A first well region 103 is disposed in the substrate 101 and has a second conductivity type opposite to that of the substrate 101. The first well region 103 is, for example, an n-type well region. A second well region 105 is also disposed in the substrate 101 and laterally separated from the first well region 103. The second well region 105 has the first conductivity type the same as that of the substrate 101. The second well region 105 is, for example, a p-type well region. A first contact region 111 and a third contact region 113 are disposed in the first well region 103 and laterally separated from each other. The first contact region 111 has the first conductivity type, for example, a p-type heavily doped region, and the third contact region 113 has the second conductivity type, for example, an n-type heavily doped region. The doping concentrations of the first contact region 111 and the third contact region 113 are both higher than the doping concentration of the first well region 103. Moreover, a second contact region 112 and a fourth contact region 114 are disposed in the second well region 105 and laterally separated from each other. The second contact region 112 has the second conductivity type, for example, an n-type heavily doped region, and the fourth contact region 114 has the first conductivity type, for example, a p-type heavily doped region. The doping concentrations of the second contact region 112 and the fourth contact region 114 are both higher than the doping concentration of the second well region 105. In this embodiment, the first contact region 111 of the first conductivity type is located between the second contact region 112 of the second conductivity type and the third contact region 113 of the second conductivity type.

As shown in FIGS. 1 and 3, the TVS diode 100A further includes an isolation region 109 disposed in the substrate 101 and surrounding the side surfaces of the first well region 103. The isolation region 109 may be a deep trench isolation (DTI) structure or other isolation structures. The isolation region 109 may be formed by etching the substrate 101 to form a deep trench surrounding the first well region 103. Then, the deep trench is filled with a dielectric or insulating material, such as silicon oxide, silicon nitride, silicon oxynitride, a combination thereof, or other suitable dielectric or insulating materials. Thereafter, a chemical mechanical planarization (CMP) process is performed on the substrate 101 to form the isolation region 109 with the DTI structure. In one embodiment, as shown in FIG. 1, the isolation region 109 may continuously surround the periphery of the first well region 103. In another embodiment, the isolation region 109 may discontinuously surround the periphery of the first well region 103. Furthermore, in one embodiment, as shown in FIG. 3, the bottom surface of the isolation region 109 may be flush with the bottom surface of the first well region 103. In another embodiment, the bottom surface of the isolation region 109 may be lower than the bottom surface of the first well region 103.

As shown in FIG. 3, the first contact region 111 and the third contact region 113 in the first well region 103 are electrically connected to a metal layer 120A through several contact plugs 122, respectively, and further electrically coupled to an input terminal (not shown) of a circuit. In addition, the second contact region 112 and the fourth contact region 114 in the second well region 105 are electrically connected to a metal layer 120B through several contact plugs 122, respectively, and further electrically coupled to a ground terminal (not shown) of the circuit. These contact plugs 122 may be formed within an interlayer dielectric (ILD) layer (not shown) on the substrate 101. The metal layer 120A and the metal layer 120B may be different portions of a first metal layer formed on the ILD layer. The metal layer 120A and the metal layer 120B may be formed by deposition and patterning processes.

The TVS diode 100A may be used as an overvoltage and electrostatic discharge (ESD) protection component, and is connected in parallel with the circuit to be protected. When a transient voltage, such as a surge, is applied to the circuit and reaches the breakdown voltage of the TVS diode 100A, the TVS diode 100A turns on. The transient current enters the first contact region 111 from the input terminal through the metal layer 120A and the contact plug 122. Next, the transient current flows through the first well region 103, the substrate 101 and the second well region 105, and flows into the second contact region 112. Finally, the second contact region 112 is electrically connected to the ground terminal through the contact plug 122 and the metal layer 120B, thereby absorbing the overcurrent generated by the abnormal overvoltage, and discharging the overcurrent to the ground terminal. Therefore, the TVS diode 100A suppresses the overvoltage exceeding its breakdown voltage, generating a clamping voltage to protect the downstream circuit. Furthermore, the TVS diode 100A may be used as a unidirectional and/or bidirectional component. In this case, the transient current enters the fourth contact region 114 through the metal layer 120B and the contact plug 122, flowing through the second well region 105, the substrate 101, and the first well region 103, and into the third contact region 113. Finally, the transient current flows out through the contact plug 122 and the metal layer 120A. Therefore, the TVS diode 100A may be used in DC circuits and AC circuits.

According to some embodiments of the present disclosure, the bottom surface of the isolation region 109 may be flush with or lower than the bottom surface of the first well region 103. In addition, the isolation region 109 may continuously or discontinuously surround all side surfaces of the first well region 103. These configurations of the isolation region 109 all block the PN junction between the substrate 101 and the side surfaces of the first well region 103 in the horizontal direction. When the isolation region 109 continuously surrounds all side surfaces of the first well region 103, and its bottom surface is lower than that of the first well region 103, the PN junction between the substrate 101 and the side surfaces of the first well region 103 is more effectively blocked. Using the isolation region 109, there is no PN junction between the substrate 101 and the first well region 103 in the horizontal direction. The PN junction between the substrate 101 and the bottom surface of the first well region 103 in the vertical direction remains. Therefore, the PN junction between the substrate 101 and the first well region 103 is reduced, resulting in a smaller depletion layer area of the PN junction, thereby reducing the capacitance and shortening the response time of the TVS diode 100A to meet high-speed transmission requirements.

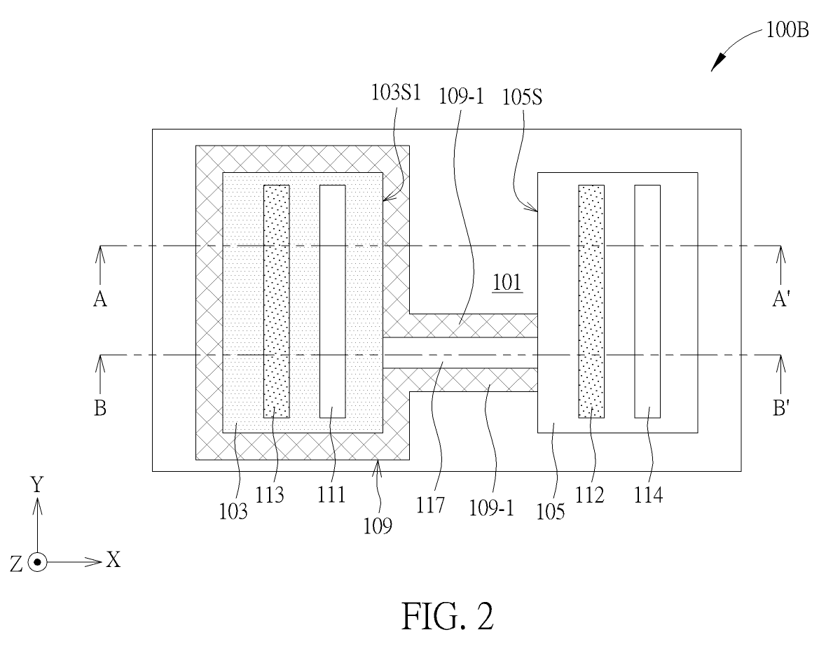

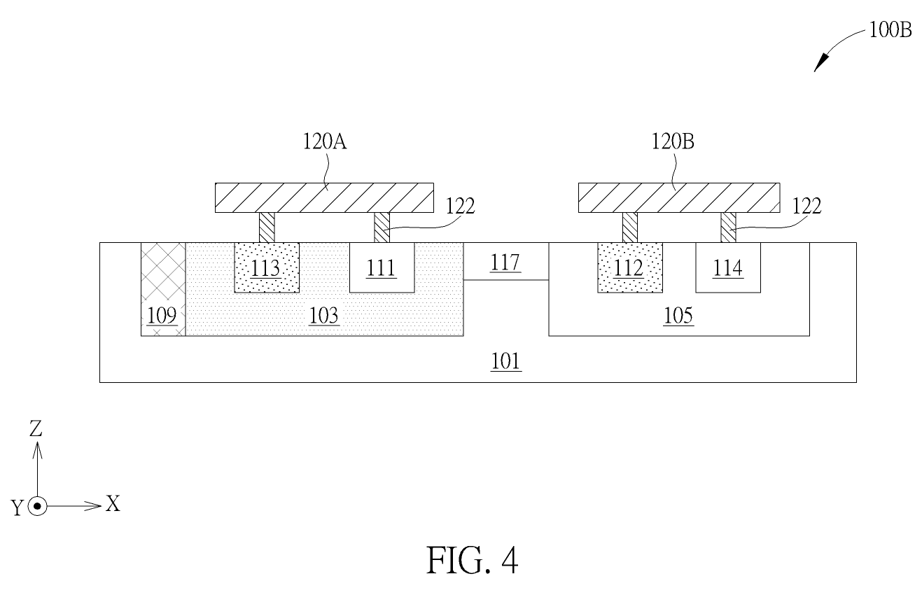

FIG. 2 is a top view of a TVS diode 100B according to another embodiment of the present disclosure. FIG. 3 is a cross-sectional view of the TVS diode 100B taken along the line A-A’ in FIG. 2 according to an embodiment of the present disclosure. FIG. 4 is a cross-sectional view of the TVS diode 100B taken along the line B-B’ in FIG. 2 according to an embodiment of the present disclosure. As shown in FIGS. 2 and 4, the TVS diode 100B may optionally include a first doped region 117 having the first conductivity type in the substrate 101. The first doped region 117 is, for example, a p-type heavily doped region, located between the first well region 103 and the second well region 105, and the doping concentration of the first doped region 117 is higher than that of the substrate 101. In this embodiment, the second contact region 112 of the second conductivity type in the second well region 105 is closer to the first well region 103 than the fourth contact region 114 of the first conductivity type, and the first doped region 117 is located between the first contact region 111 and the second contact region 112. In one embodiment, as shown in FIG. 2, the first doped region 117 continuously extends from a first side surface 103S1 on the right side of the first well region 103 to a side surface 105S on the left side of the second well region 105, and the first doped region 117 is in direct contact with both the first side surface 103S1 and the side surface 105S. In another embodiment, the first doped region 117 may be laterally separated from the first side surface 103S1 of the first well region 103 and the side surface 105S of the second well region 105, and not in direct contact with the first side surface 103S1 and the side surface 105S. In addition, as shown in FIG. 4, the bottom surface of the first doped region 117 is higher than the bottom surface of the first well region 103 and the bottom surface of the second well region 105. The top surface of the first doped region 117 is flush with the top surface of the substrate 101.

The doping concentration of the first doped region 117 is higher than that of the substrate 101. This reduces the electric field strength required for driving ionization by collision at the PN junction, thereby reducing the breakdown voltage of the TVS diode 100B. For example, compared with the TVS diode 100A in FIG. 1, the breakdown voltage of the TVS diode 100B in FIG. 2 is reduced from about 30V to about 7V or 8V. Furthermore, the doping concentration of the first doped region 117 may be adjusted according to the voltage operating range required by the downstream circuit to be protected, thereby ensuring the breakdown voltage of the TVS diode 100B meets the downstream circuit’s voltage requirements.

In addition, as shown in FIG. 2, the isolation region 109 of the TVS diode 100B further includes a first portion 109-1 disposed on two opposite sides of the first doped region 117. The first portion 109-1 continuously extends from the first side surface 103S1 on the right side of the first well region 103 to the side surface 105S on the left side of the second well region 105. The first portion 109-1 is in direct contact with both the first side surface 103S1 and the side surface 105S. From a top view, the first doped region 117 and the first portion 109-1 of the isolation region 109 are perpendicular to both the first side surface 103S1 of the first well region 103 and the side surface 105S of the second well region 105. In one embodiment, as shown in FIG. 2, the isolation region 109 may continuously surround most of the side surfaces of the first well region 103 and the two opposite sides of the first doped region 117. The first portion 109-1 of the isolation region 109 more effectively prevents lateral diffusion of dopants from the first well region 103 and the first doped region 117 into the substrate 101 along the Y-axis direction. In another embodiment, the isolation region 109 may discontinuously surround most of the side surfaces of the first well region 103 and the two opposite sides of the first doped region 117. The details of other features of the TVS diode 100B may refer to the aforementioned descriptions of the TVS diode 100A in FIGS. 1 and 3, and will not be repeated here.

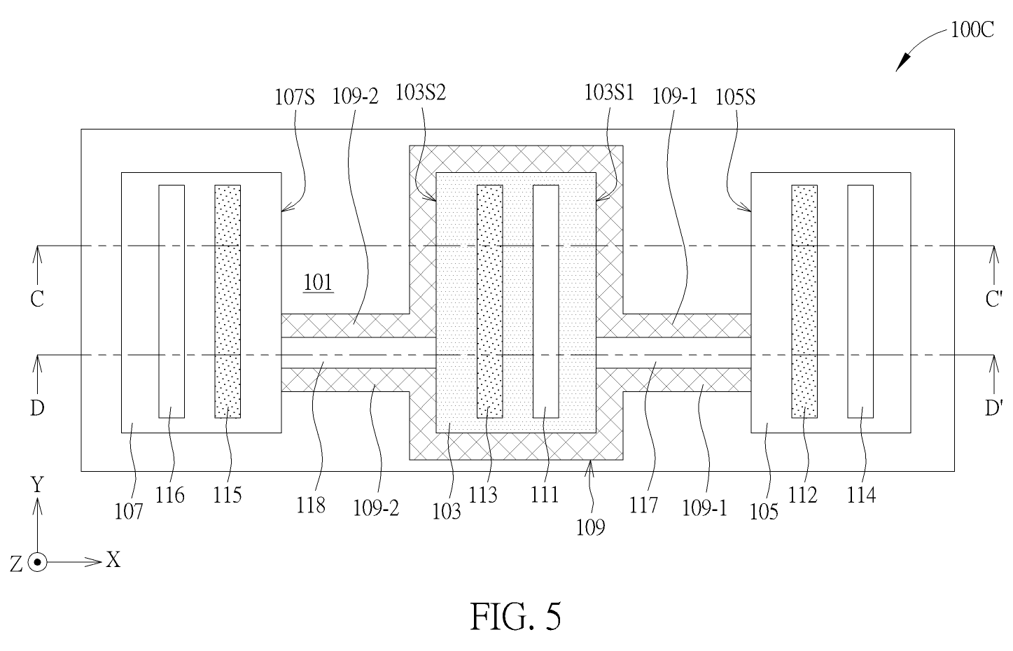

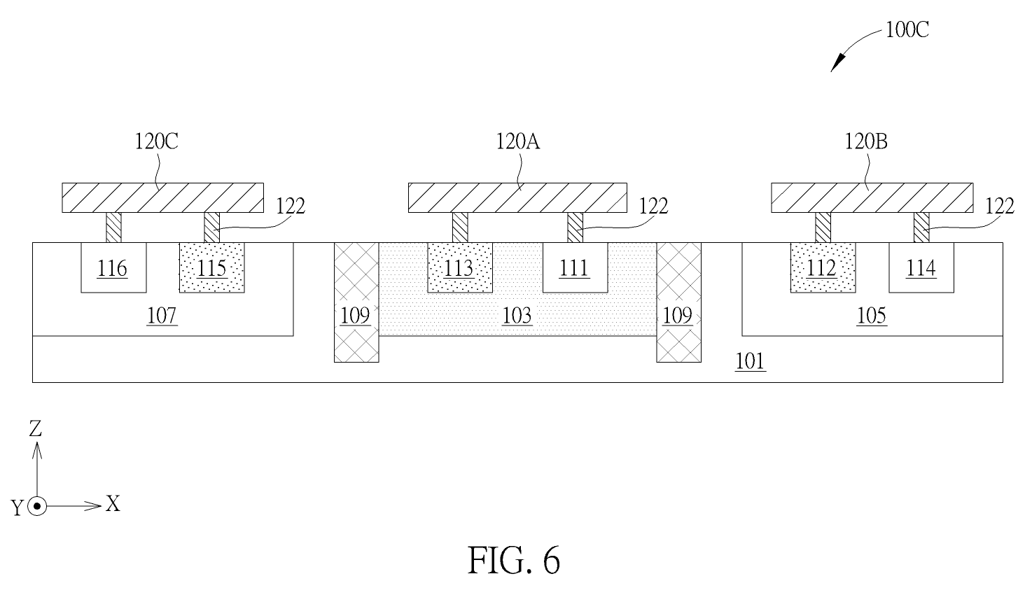

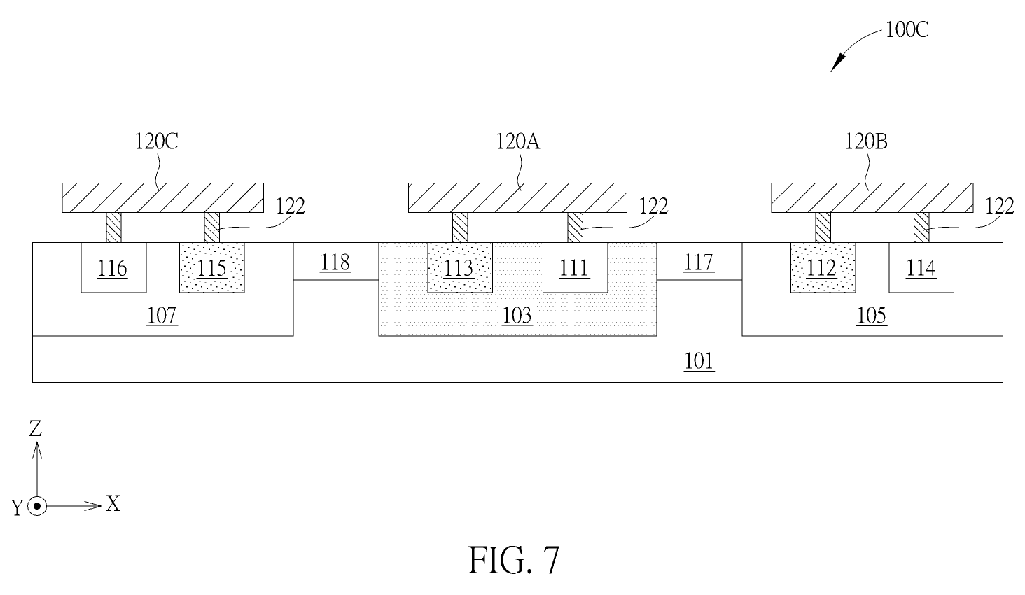

FIG. 5 is a schematic top view of a TVS diode 100C according to another embodiment of the present disclosure. FIG. 6 is a schematic cross-sectional view of the TVS diode 100C taken along the line C-C’ in FIG. 5 according to an embodiment of the present disclosure. FIG. 7 is a schematic cross-sectional view of the TVS diode 100C taken along the line D-D’ in FIG. 5 according to an embodiment of the present disclosure. As shown in FIG. 5, the TVS diode 100C further includes a third well region 107 of the first conductivity type, such as a p-type well region, disposed in the substrate 101. The third well region 107 is laterally separated from the first well region 103, and the first well region 103 is located between the second well region 105 and the third well region 107.

In addition, the TVS diode 100C includes a fifth contact region 115 and a sixth contact region 116, both disposed in the third well region 107 and laterally separated from each other. The fifth contact region 115 has the second conductivity type, such as an n-type heavily doped region. The sixth contact region 116 has the first conductivity type, such as a p-type heavily doped region. The doping concentrations of both the fifth contact region 115 and the sixth contact region 116 are higher than that of the third well region 107. In this embodiment, the fifth contact region 115 of the second conductivity type in the third well region 107 is closer to the first well region 103 than the sixth contact region 116 of the first conductivity type. The fifth contact region 115 is located between the third contact region 113 and the sixth contact region 116. Using the first well region 103 as the center of symmetry, the TVS diode 100C exhibits a bilaterally symmetrical layout.

Referring to FIG. 6, the fifth contact region 115 and the sixth contact region 116 in the third well region 107 are electrically connected to the metal layer 120C via the contact plugs 122, respectively, and further electrically coupled to a circuit’s ground terminal. The metal layer 120A, the metal layer 120B and the metal layer 120C may be different portions of a first metal layer formed on an interlayer dielectric (ILD) layer (not shown). The metal layer 120A is electrically coupled to the circuit’s input terminal. The metal layer 120B and the metal layer 120C are both electrically coupled to the circuit’s ground terminal. The TVS diode 100C may be used as an overvoltage and electrostatic discharge (ESD) protection component, connected in parallel with the circuit to be protected. When a transient voltage is applied to the circuit and reaches the breakdown voltage of the TVS diode 100C, the TVS diode 100C turns on, and the transient current enters the first contact region 111 from the input terminal via the metal layer 120A and the contact plug 122. Then, the transient current flows through the first well region 103, the substrate 101, the second well region 105, and the third well region 107, and flows into the second contact region 112 and the fifth contact region 115. Finally, the second contact region 112 and the fifth contact region 115 are electrically connected to the ground terminal through the contact plugs 122, the metal layer 120B and the metal layer 120C, thereby absorbing the overcurrent generated by the abnormal overvoltage and discharging it to the ground terminal. Therefore, the TVS diode 100C suppresses the excessive voltage above its breakdown voltage and generates a clamping voltage to protect the downstream circuit. Furthermore, the TVS diode 100C may be used as a unidirectional and/or bidirectional component. The transient current may enter the fourth contact region 114 and the sixth contact region 116 via the metal layer 120B, the metal layer 120C, and the contact plugs 122, flowing through the second well region 105, the third well region 107, the substrate 101, and the first well region 103, and flowing into the third contact region 113. Finally, the transient current flows out via the contact plug 122 and the metal layer 120A. Therefore, the TVS diode 100C may be used in DC circuits and AC circuits.

In addition, as shown in FIG. 6, in this embodiment, the bottom surface of the isolation region 109 in the TVS diode 100C may be lower than the bottom surface of the first well region 103, and also lower than the bottom surfaces of both the second well region 105 and the third well region 107. In another embodiment, the bottom surface of the isolation region 109 in the TVS diode 100C may be flush with the bottom surface of the first well region 103, and also flush with the bottom surfaces of both the second well region 105 and the third well region 107.

As shown in FIGS. 5 and 7, the TVS diode 100C may optionally include a first doped region 117 of the first conductivity type and a second doped region 118 of the first conductivity type, both disposed in the substrate 101. The first doped region 117 and the second doped region 118 are, for example, both p-type heavily doped regions. The first doped region 117 is located between the first well region 103 and the second well region 105. The second doped region 118 is located between the first well region 103 and the third well region 107. The doping concentrations of both the first doped region 117 and the second doped region 118 are higher than that of the substrate 101. In one embodiment, as shown in FIG. 5, the first doped region 117 may continuously extend from the first side surface 103S1 (on the right side of the first well region 103) to the side surface 105S (on the left side of the second well region 105). The first doped region 117 may be in direct contact with the first side surface 103S1 and the side surface 105S. The second doped region 118 may continuously extend from the second side surface 103S2 (on the left side of the first well region 103) to the side surface 107S (on the right side of the third well region 107). The second doped region 118 may be in direct contact with the second side surface 103S2 and the side surface 107S. In another embodiment, the first doped region 117 and the second doped region 118 may be both laterally separated from all the first well region 103, the second well region 105, and the third well region 107, and not in direct contact with the first side surface 103S1, the second side surface 103S2, the side surface 105S, and the side surface 107S. In addition, as shown in FIG. 7, the bottom surfaces of both the first doped region 117 and the second doped region 118 are higher than the bottom surface of the first well region 103. The top surfaces of both the first doped region 117 and the second doped region 118 are flush with the top surface of the substrate 101.

In addition, as shown in FIG. 5, the isolation region 109 of the TVS diode 100C further includes a first portion 109-1 and a second portion 109-2. The first portion 109-1 is disposed on two opposite sides of the first doped region 117. The second portion 109-2 is disposed on two opposite sides of the second doped region 118. The first portion 109-1 may continuously extend from the first side surface 103S1 (on the right side of the first well region 103) to the side surface 105S (on the left side of the second well region 105). The second portion 109-2 may continuously extend from the second side surface 103S2 (on the left side of the first well region 103) to the side surface 107S (on the right side of the third well region 107). The first portion 109-1 is in direct contact with the first side surface 103S1 and the side surface 105S. The second portion 109-2 is in direct contact with the second side surface 103S2 and the side surface 107S. From a top view, the first doped region 117 and the first portion 109-1 of the isolation region 109 are perpendicular to the first side surface 103S1 of the first well region 103. The second doped region 118 and the second portion 109-2 of the isolation region 109 are perpendicular to the second side surface 103S2 of the first well region 103. In addition, from the top view, the long axes (e.g., the Y axis) of the first contact region 111, the second contact region 112, the third contact region 113, the fourth contact region 114, the fifth contact region 115, and the sixth contact region 116 are parallel to each other. In one embodiment, as shown in FIG. 5, the isolation region 109 may continuously surround most of the side surfaces of the first well region 103, the two opposite sides of the first doped region 117, and the two opposite sides of the second doped region 118. In another embodiment, the isolation region 109 may discontinuously surround most of the side surfaces of the first well region 103, the two opposite sides of the first doped region 117, and the two opposite sides of the second doped region 118. The details of other features of the TVS diode 100C may refer to the aforementioned descriptions of the TVS diode 100A in FIG. 1 and the TVS diode 100B in FIG. 2, which will not be repeated here.

According to some embodiments of the present disclosure, the isolation region is disposed between the substrate and the first well region of opposite conductivity types. The isolation region is formed by etching the substrate and filling it with a dielectric or insulating material to create a deep trench isolation structure. This isolation region surrounds the periphery of the first well region to block the PN junction between the substrate and the sides of the first well region, thereby eliminating the PN junction between the substrate and the first well region in the horizontal direction and leaving only a PN junction in the vertical direction. As a result, the PN junction area and the depletion layer area are reduced, thereby reducing the capacitance of the TVS diodes and shortening their response time. Therefore, the switching speed of the TVS diodes is improved to meet the requirements of high-speed transmission.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transient voltage suppression diode, comprising:
a substrate, having a first conductivity type;
a first well region, having a second conductivity type, and disposed in the substrate;
a first contact region, having the first conductivity type, disposed in the first well region, and configured to be electrically coupled to an input terminal;
a second well region, having the first conductivity type, disposed in the substrate, and laterally separated from the first well region;
a second contact region, having the second conductivity type, disposed in the second well region, and configured to be electrically coupled to a ground terminal; and
an isolation region, disposed in the substrate, and surrounding side surfaces of the first well region.

2. The transient voltage suppression diode of claim 1, wherein a bottom surface of the isolation region is flush with or lower than a bottom surface of the first well region.

3. The transient voltage suppression diode of claim 1, wherein the isolation region comprises a deep trench isolation structure, and continuously surrounds the side surfaces of the first well region.

4. The transient voltage suppression diode of claim 1, further comprising a first doped region, having the first conductivity type, and disposed between the first well region and the second well region, wherein a doping concentration of the first doped region is higher than a doping concentration of the substrate.

5. The transient voltage suppression diode of claim 4, wherein the first doped region continuously extends from a side of the first well region to a side of the second well region.

6. The transient voltage suppression diode of claim 4, wherein a bottom surface of the first doped region is higher than both a bottom surface of the first well region and a bottom surface of the second well region, and a top surface of the first doped region is flush with a top surface of the substrate.

7. The transient voltage suppression diode of claim 4, wherein the isolation region further comprises a first portion disposed on two opposite sides of the first doped region, and the first portion continuously extends from a side of the first well region to a side of the second well region.

8. The transient voltage suppression diode of claim 7, wherein from a top view, the first doped region and the first portion of the isolation region are perpendicular to both the side of the first well region and the side of the second well region.

9. The transient voltage suppression diode of claim 4, wherein the isolation region continuously surrounds the side surfaces of the first well region and two opposite sides of the first doped region.

10. The transient voltage suppression diode of claim 1, further comprising:
a third contact region, having the second conductivity type, disposed in the first well region, laterally separated from the first contact region, and configured to be electrically coupled to the input terminal; and
a fourth contact region, having the first conductivity type, disposed in the second well region, laterally separated from the second contact region, and configured to be electrically coupled to the ground terminal,
wherein the first contact region is located between the second contact region and the third contact region.

11. The transient voltage suppressor diode of claim 10, wherein a doping concentration of the first contact region and a doping concentration of the third contact region are both higher than a doping concentration of the first well region, and a doping concentration of the second contact region and a doping concentration of the fourth contact region are both higher than a doping concentration of the second well region.

12. The transient voltage suppression diode of claim 10, further comprising:
a third well region, having the first conductivity type, disposed in the substrate, and laterally separated from the first well region, wherein the first well region is located between the second well region and the third well region;
a fifth contact region, having the second conductivity type, disposed in the third well region, and configured to be electrically coupled to the ground terminal; and
a sixth contact region, having the first conductivity type, disposed in the third well region, laterally separated from the fifth contact region, and configured to be electrically coupled to the ground terminal, wherein the fifth contact region is located between the third contact region and the sixth contact region.

13. The transient voltage suppressor diode of claim 12, wherein a doping concentration of the fifth contact region and a doping concentration of the sixth contact region are both higher than a doping concentration of the third well region.

14. The transient voltage suppression diode of claim 12, further comprising:
a first doped region, having the first conductivity type, and located between the first well region and the second well region; and
a second doped region, having the first conductivity type, and located between the first well region and the third well region,
wherein a doping concentration of the first doped region and a doping concentration of the second doped region are both higher than a doping concentration of the substrate.

15. The transient voltage suppression diode of claim 14, wherein the first doped region continuously extends from a first side of the first well region to a side of the second well region, and the second doped region continuously extends from a second side of the first well region to a side of the third well region.

16. The transient voltage suppression diode of claim 14, wherein a bottom surface of the first doped region and a bottom surface of the second doped region are both higher than a bottom surface of the first well region, and a top surface of the first doped region and a top surface of the second doped region are both flush with a top surface of the substrate.

17. The transient voltage suppression diode of claim 14, wherein the isolation region further comprises:
a first portion, disposed on two opposite sides of the first doped region, wherein the first portion continuously extends from a first side of the first well region to a side of the second well region; and
a second portion, disposed on two opposite sides of the second doped region, wherein the second portion continuously extends from a second side of the first well region to a side of the third well region.

18. The transient voltage suppression diode of claim 17, wherein from a top view, the first doped region and the first portion of the isolation region are perpendicular to the first side of the first well region, and the second doped region and the second portion of the isolation region are perpendicular to the second side of the first well region.

19. The transient voltage suppression diode of claim 14, wherein the isolation region continuously surrounds the side surfaces of the first well region, two opposite sides of the first doped region, and two opposite sides of the second doped region.

20. The transient voltage suppressor diode of claim 12, wherein from a top view, long axes of the first contact region, the second contact region, the third contact region, the fourth contact region, the fifth contact region and the sixth contact region are parallel to each other.
